(19) United States
(12) Patent Application Publication
(10) Pub. No.: US 2005/0110513 A1
(43) Pub. Date: May 26, 2005

(54) Semiconductor test module and method of testing semiconductor device

(75) Inventors: Tatsuo Osada, Fukuoka (JP); Kenji Goto, Fukuoka (JP); Koji Tsurumura, Fukuoka (JP); Masaru Fujimori, Fukuoka (JP); Yasuyuki Nakashima, Fukuoka (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/969,988

(22) Filed: Oct. 22, 2004

(30) Foreign Application Priority Data
Oct. 22, 2003 (JP) 2003-361572

(51) Int. Cl. G01R 31/26

(52) U.S. Cl. 324/765

(57) ABSTRACT

A semiconductor test module comprises an interface that inputs test condition information showing a test condition of a subject to be tested from an external testing device which tests electric characteristics of the subject, and that outputs test result information showing a result of testing the subject to the external testing device; a first storage section that stores the test condition information; a processor that processes the test condition information independently of the external testing device; an output section that outputs a test signal based on the test condition information to the subject in parallel with the external testing device, following an instruction from the processor; an input section that inputs a response signal from the subject in response to the test signal; and a second storage section that stores information based on the response signal as the test result information.

### CROSS-REFERENCE TO RELATED APPLICATION

This application is based upon and claims the benefit of priority from the prior Japanese Patent Applications No. 2003-361572, filed on Oct. 22, 2003, the entire contents of which are incorporated herein by reference.

### BACKGROUND OF THE INVENTION

1. Field of the Invention

The present invention relates to a semiconductor test module and a method of testing a semiconductor device.

2. Background Art

In testing a semiconductor device, one measuring and testing device (hereinafter simply referred to as a tester) is used to sequentially measure various electric characteristics within the semiconductor device. Due to the increase in the scale of the semiconductor device, the device includes a diversified range of functions in recent years. Therefore, the number of items to be tested by the tester increases, and the time of testing the semiconductor increases accordingly.

In order to solve these problems associated with the testing of the semiconductor device, the number of testers should be increased or the number of test items should be decreased. However, the semiconductor tester is very expensive and requires a large installation area. Therefore, increasing the number of testers brings about an increase in the manufacturing cost of the semiconductor device. Further, decreasing the number of test items makes it difficult to guarantee the quality of the semiconductor device, resulting in the loss of reliability of the semiconductor device.

### SUMMARY OF THE INVENTION

A semiconductor test module according to an embodiment of the invention comprises an interface that inputs test condition information showing a test condition of a subject to be tested from an external testing device which tests electric characteristics of the subject, and that outputs test result information showing a result of testing the subject to the external testing device; a first storage section that stores the test condition information; a processor that processes the test condition information independently of the external testing device; an output section that outputs a test signal based on the test condition information to the subject in parallel with the external testing device, following an instruction from the processor; an input section that inputs a response signal from the subject in response to the test signal; and a second storage section that stores information based on the response signal as the test result information.

A method of testing a semiconductor device for testing a subject by using a semiconductor test module, the test module having an interface communicable with an external testing device which tests electric characteristics of the subject, a processor that processes information from the interface, an output section that outputs a test signal for testing the subject to the subject, and an input section that inputs a response signal from the subject in response to the test signal, wherein

the method of testing a semiconductor device according to an embodiment of the invention comprises inputting test condition information via the interface, the test condition information showing a condition for testing the subject from the external testing device; processing the test condition information in the processor independently of the external testing device; outputting the test signal based on the test condition information from the output section to the subject in parallel with the external testing device; and inputting the response signal via the input section.

### BRIEF DESCRIPTION OF THE DRAWINGS

FIG. 1 is a block diagram of the configuration of a test module 100 according to a first embodiment of the present invention;

FIG. 2 is a flowchart of test operations of the test module 100 and the external tester 300;

FIG. 3 is a block diagram illustrating in further detail the inside of the test module 100;

FIG. 4 is a circuit diagram of the circuit within the DUT 400;

FIG. 5 is a graph of the voltage of the test signal;

FIG. 6 is a graph of the voltage of the response signal;

FIG. 7 is a flowchart of a sequential search method;

FIG. 8 is a flowchart of a sequential search method;

FIG. 9 is a flowchart of the correction operation of the test module 100;

FIG. 10 is a block diagram of the configuration of a test module 200 according to a second embodiment of the present invention; and

FIG. 11 is a flowchart of the test operation of the test module 200.

### DETAILED DESCRIPTION OF THE INVENTION

Embodiments of the present invention will be explained below in detail with reference to the accompanying drawings. Note that the invention is not limited by the embodiments.

A semiconductor device test module (hereinafter referred to as a test module) according to an embodiment of the present invention is configured to test the semiconductor device independently of the tester, and test the semiconductor device in parallel with the tester. With this arrangement, the test module can test the semiconductor device in a shorter time than is required in the past.

### First Embodiment

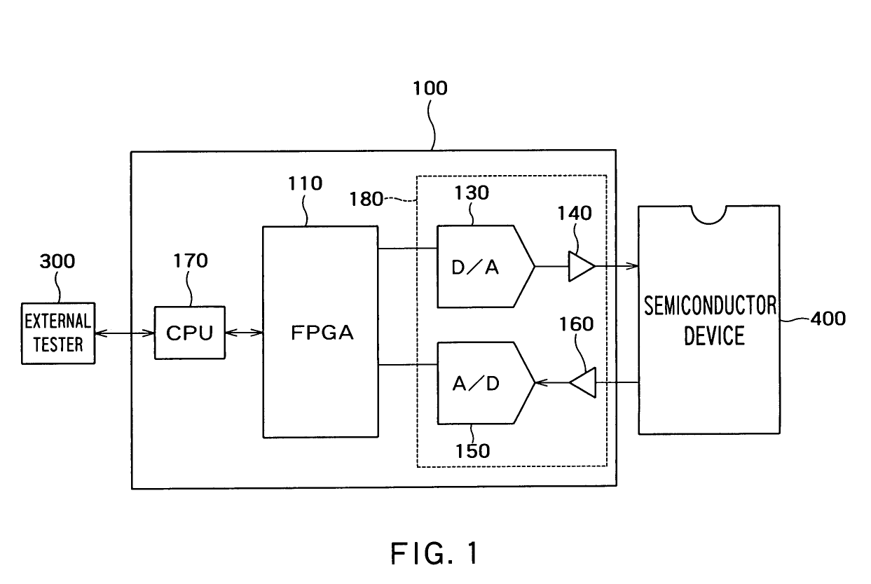

FIG. 1 is a block diagram of the configuration of a test module 100 according to a first embodiment of the present invention. The test module 100 includes an FPGA (Field Programmable Gate Array) 110, a D/A converter 130, an output buffer 140, an A/D converter 150, an input buffer 160, and a CPU 170.

The CPU 170 is communicably connected to an external tester 300. The external tester 300 is electrically connected to a DUT (Device Under Tester) 400 without passing through the test module 100, and can independently test the DUT 400. The FPGA 110 is further connected to the D/A converter 130, the A/D converter 150, and the CPU 170.

The D/A converter 130 and the A/D converter 150 are connected to the DUT 400 via the output buffer 140 and the input buffer 160 respectively.

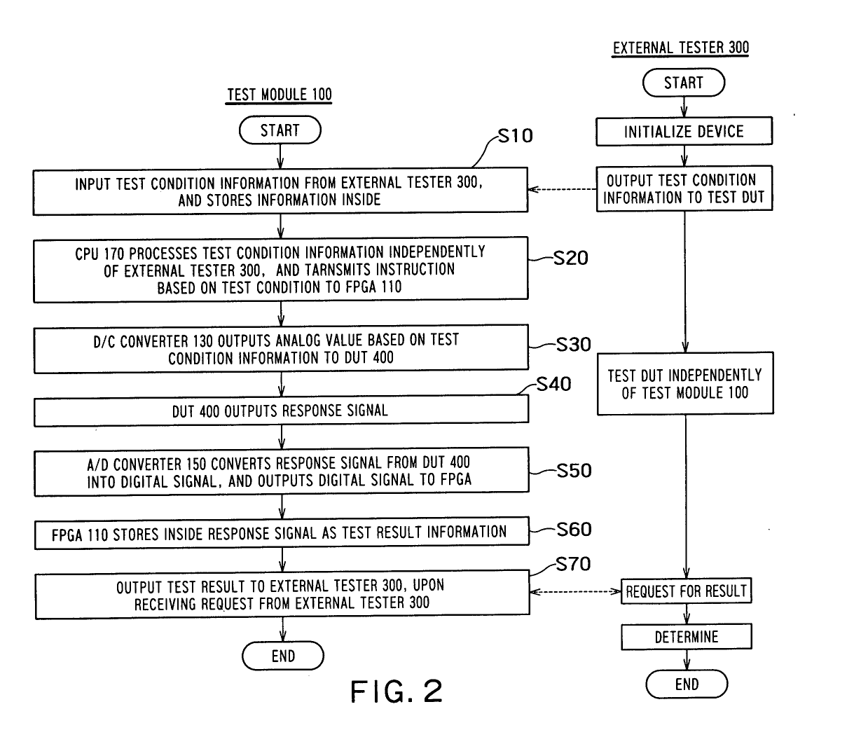

FIG. 2 is a flowchart of test operations of the test module 100 and the external tester 300. A broken-line arrow mark indicates transmission and reception of signals. The FPGA 110 inputs test condition information to test the DUT 400 from the external tester 300 via the CPU 170, and stores this test condition information into the FPGA 110 (S10). The CPU 170 processes the test condition information independently of the external tester 300, and transmits an instruction based on the test condition to the FPGA 110 (S20). The FPGA 110 controls the D/A converter 130 based on this instruction, and accordingly the D/A converter 130 outputs an analog value to the DUT 400 based on the test condition information (S30).

The DUT 400 outputs a response signal following the electric characteristics of the DUT 400 in response to a certain input signal (S40). The A/D converter 150 converts the response signal from the DUT 400 into a digital signal, and transmits the digital signal to the FPGA 110 (S50). The FPGA 110 stores the digitalized response signal as test result information in the FPGA 110 (S60). The processing at steps S20 to S60 is executed repeatedly. Result information of a series of test carried out based on the test condition is stored in the FPGA 110. After the test, the FPGA 110 outputs the test result to the external tester 300 upon receiving a request from the external tester 300 (S70).

The test module 100 executes the test independently of the test carried out by the external tester 300. In order to avoid a mutual interference between the signal concerning the test carried out by the external tester 300 and the signal concerning the test carried out by the test module 100, the test module 100 tests a circuit portion electrically isolated from a circuit portion that the external tester 300 tests during the same period. As a result, the test module 100 can test the same DUT 400 in parallel with the external tester 300.

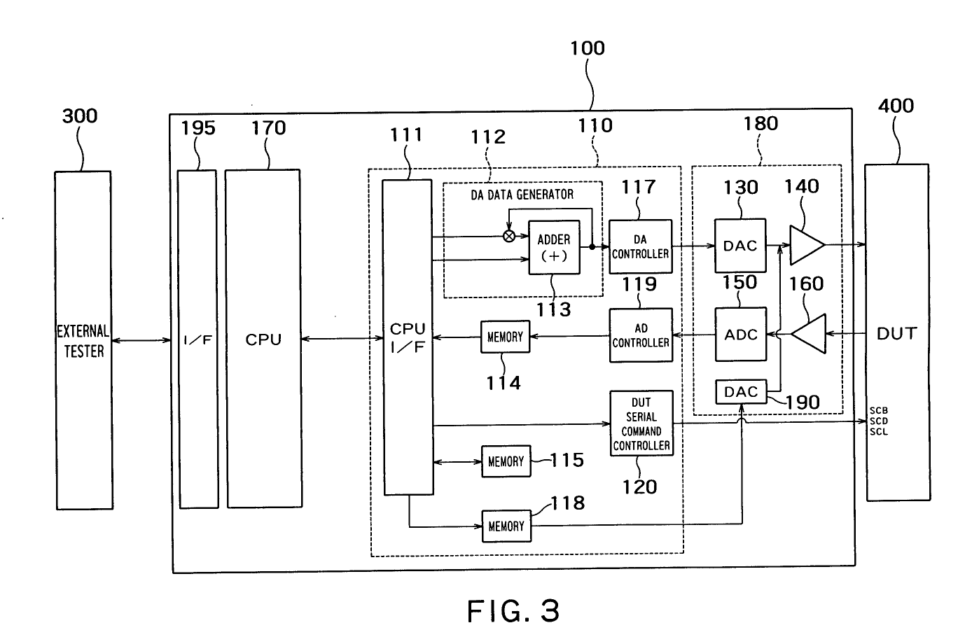

FIG. 3 is a block diagram illustrating in further detail the inside of the test module 100. The FPGA 110 includes a CPU interface 111, a DA data generator 112, memories 114, 115, and 118, a DA controller 117, an AD controller 119, and a DUT serial command controller 120. An analog section 180 further includes a correction D/A converter 190. The test module 100 includes an interface 195 which makes it possible to communicate with the external tester 300.

The CPU 170 can communicate with the external tester 300 via the interface 195. The CPU 170 and the FPGA 110 can communicate with each other via the CPU interface 111.

The test condition information from the external tester 300 is transmitted to the CPU 170 via the interface 195. The CPU 170 stores the test condition information into the memory 115 via the CPU interface 111. The test condition information includes a change range of a voltage of the test signal, a voltage step width for a staged change of the voltage of the test signal (hereinafter also referred to as input resolution), time period to supply the test signal to the DUT 400 at a certain voltage step, a method of searching a desired test signal within a change range, and a response signal that becomes a basis of the search. The CPU 170 can sequentially read the test condition information stored in the memory 115, process the test condition information, and control the FPGA 110 based on this processing. The test condition information may include information of a number of steps to change the voltage of the test signal instead of the voltage step width.

An output section of the test module 100 includes the DA data generator 112, the DA controller 117, the D/A converter 130, and the output buffer 140. The output section of the test module 100 is connected between the CPU interface 111 and the DUT 400. In the present embodiment, the DA data generator 112 includes an adder 113, and transmits a digital signal following the test condition information to the DA controller 117. The DA controller 117 controls the D/A converter 130. Based on this control, the D/A converter 130 converts the digital signal into an analog signal, and transmits the analog signal to the amplifier 140. The analog signal amplified by the amplifier 140 is supplied to the DUT 400 as a test signal.

The adder 113 sequentially adds a voltage of a predetermined step width to a minimum voltage in order to supply at stages a voltage from the minimum voltage to a maximum voltage within the change range of the test signal to the DUT 400. The adder 113 continues this addition until when the voltage of the response signal from the DUT 400 becomes a predetermined voltage.

On the other hand, an input section of the test module 100 includes the input buffer 160, the A/D converter 150, the AD controller 119, and the memory 114. The input section of the test module 100 is connected between the CPU interface 111 and the DUT 400. The test signal is output from the DUT 400 as a response signal via a circuit to be tested within the DUT 400. This response signal is an analog signal, and the response signal amplified via the input buffer 160 is transmitted to the D/A converter 150. The A/D converter 150 converts the response signal into a digital signal. This digital signal is stored as test result information into the memory 114 via the AD controller 119.

The DUT serial command controller 120 can change the serial command of the DUT 400. The change of the serial command is the change of the level of a power source voltage to be supplied within the DUT 400 during the test of the DUT 400, for example.

The D/A converter 190 and the memory 118 are connected to between the output buffer 140 and the interface 195. The D/A converter 190 and the memory 118 are used to correct the test module 100. When the test signal output from the external tester 300 and the test signal output from the test module 100 are different under the same test condition information, for example, the test module 100 cannot accurately test the DUT 400. Therefore, the D/A converter 190 corrects the analog signal output from the D/A converter 130. Based on this correction, the test module 100 can output the test signal equal to that from the external tester 300 under the same test condition information. The memory 118 stores the corrected condition information. The D/A converter 190 adds the analog signal based on the corrected condition information to the analog signal output from the D/A converter 130.

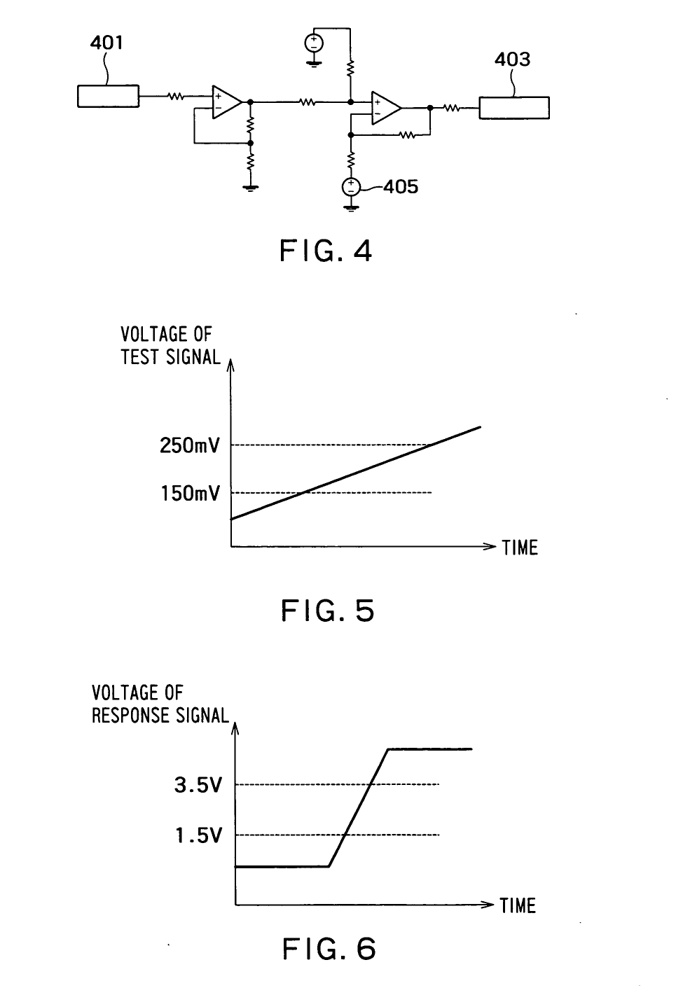

The operation that the test module 100 shown in FIG. 3 tests a circuit inside the DUT 400 shown in FIG. 4 will be explained as an example.

FIG. 4 is a circuit diagram of the circuit within the DUT 400 to be tested by the test module 100. An input 401 and an output 403 are electrically connected to the output buffer 140 and the input buffer 160 of the test module 100 respectively. A power source 405 is connected to the DUT serial command controller 120. The power source voltage is changed according to the setting of the DUT serial command controller 120. FIG. 4 shows a part of the circuit of the DUT 400, and this circuit portion is electrically independent of the circuit portion that is tested by the external tester 300.

FIG. 5 is a graph of the voltage of the test signal to be supplied from the test module 100 to the input 401. FIG. 6 is a graph of the voltage of the response signal from the output 403 to the test module 100. The test module 100 gives the test signal of 150 mV to 250 mV to the input 401, for example. The response signal is obtained in response to this test signal.

The A/D converter 150 converts the response signal into a digital signal, and stores the signal into the memory 114 as the test result information. The CPU 170 can determine pass or failure of the DUT 400 based on this test result information. The CPU 170 transmits the test result information within the memory 114 and the pass or failure result of the DUT 400 to the external tester 300 in response to the request signal from the external tester 300. As a result, the external tester 300 can obtain the same test result information as that the external tester 300 obtains when the external tester 300 tests by itself the circuit shown in FIG. 4.

For example, the test module 100 searches the test signal when the response signal changes from a voltage below 1.5V to a voltage above 3.5V (hereinafter referred to as a threshold signal), as shown in FIG. 6. As a result, the electric characteristics of the gain or the like of the circuit shown in FIG. 4 can be obtained. The external tester 300 can determine pass or failure of the DUT 400 based on the electric characteristics of the gain or the like of the DUT 400.

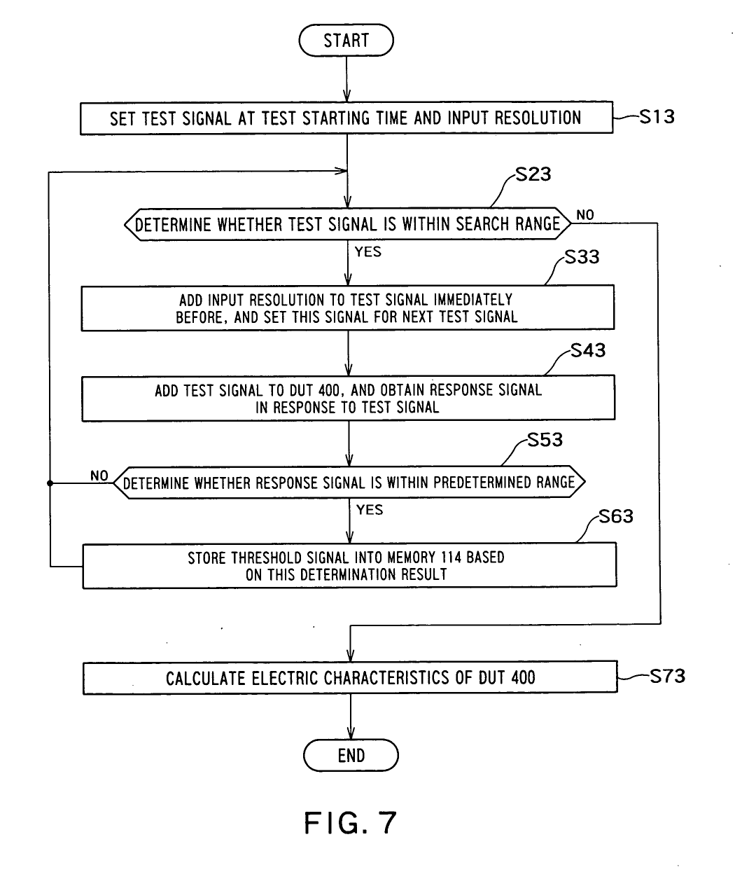

FIG. 7 is a flowchart of a method in which the test module 100 searches the threshold signal. First, the CPU 170 sets the test signal at the test starting time and sets the input resolution (S13). For example, the voltage of the test signal at the test starting time is 150 mV and the input resolution is 0.1 mV.

The CPU 170 determines whether the test signal is within the search range (S23). When the search range is 150 mV to 250 mV as shown in FIG. 5, for example, the CPU 170 determines whether the voltage of the test signal is within the range from 150 mV to 250 mV.

When the test signal is within the search range, the adder 113 adds the input resolution to the test signal immediately before, and sets this signal for the next test signal (S33). The test module 100 adds the test signal to the DUT 400, and obtains the response signal in response to the test signal (S43). If the voltage of the test signal immediately before is 200 mV, the test module 100 gives the test signal 200.1 mV to the DUT 400 for the next test signal. A voltage of the next test signal is a voltage added the input resolution to the voltage of the former test signal.

The CPU 170 then determines whether the response signal is within the predetermined range (S53). The threshold signal is stored into the memory 114 based on this determination result (S63). For example, the CPU 170 determines whether the voltage of the response signal is below 1.5 V or above 3.5 V as shown in FIG. 6. As a result, the threshold voltage when the voltage of the response signal exceeds 3.5 V is searched.

When the test signal is above the search range at step S23, the CPU 170 calculates the electric characteristics of the DUT 400 (S73). For example, the CPU 170 calculates the gain of the DUT 400 as shown in the following expression 1.
(3.5−1.5)/(VA−VB) (Expression 1)
where VA represents a voltage of the test signal when the voltage of the response signal is about 3.5 V, and VB represents a voltage of the test signal when the voltage of the response signal is about 1.5 V.

The test module 100 repeats the processing at steps S23 to S63 to sequentially output the test signals of 150 mV to 250 mV at stages, thereby searching the threshold voltage. The search method shown in FIG. 7 is hereinafter called a sequential search method. In this example, the number of steps of the test signal is 1,000(=(250−150)/0.1). Therefore, there is a case that the test module 100 must output the test signal up to 1,000 times to test the circuit shown in FIG. 4. When the time required for each step, i.e., the time required to obtain the response time since the test module 100 outputs the test signal is T₀, the time of 1.000*T₀ may be necessary to test the circuit shown in FIG. 4. Each time when the voltage of the power source 405 is changed, the test time becomes longer.

However, in the present embodiment, the DUT 400 can be tested independently of the external tester 300 and also in parallel with the tester 300. In other words, while the test module 100 is testing the circuit shown in FIG. 4, the external tester 300 can test other circuit portion within the DUT 400. Therefore, when one test module 100 is arranged for the external tester 300, the time to test the DUT 400 can be shortened. Two or more test modules 100 can be arranged in parallel with the external tester 300. This arrangement can further shorten the time to test the DUT 400.

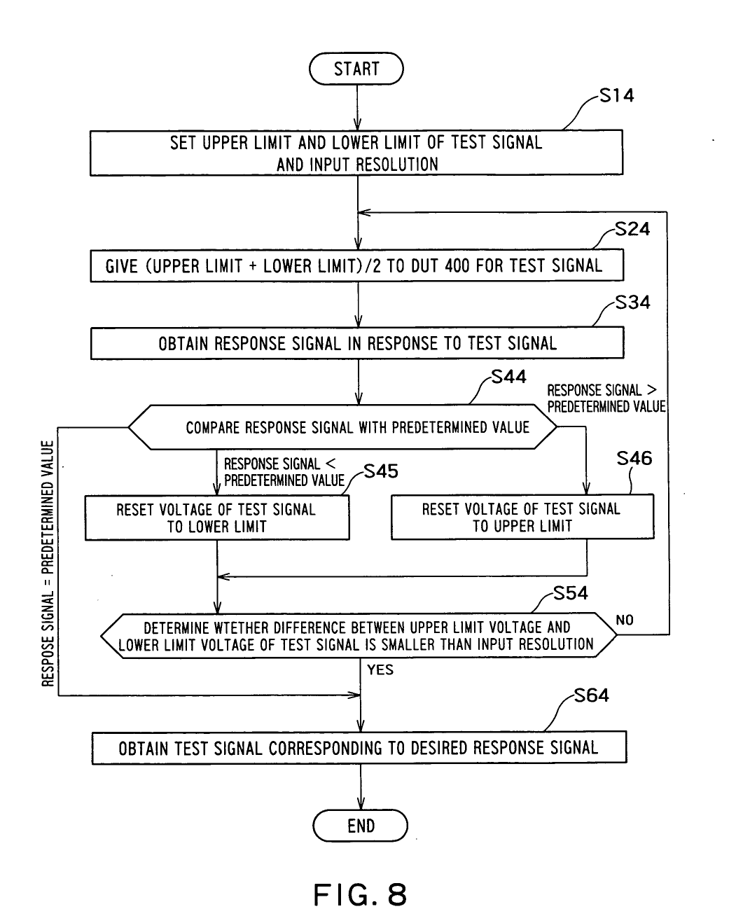

FIG. 8 is a flowchart of a method of searching the threshold signal different from the sequential search method shown in FIG. 7. The test module 100 can use any one of the search methods shown in FIG. 7 and FIG. 8.

According to this search method, an upper limit and a lower limit of the test signal and input resolution are set (S14). For example, when the search range is 150 mV to 250 mV as shown in FIG. 5, the lower limit voltage is set to 150 mV and the upper limit voltage is set to 250 mV. Next, (the upper limit+the lower limit)/2 is given to the DUT 400 for the test signal (S24). For example, (150 mV+250 mV)/2=200 mV is applied to the DUT 400 as the test signal. The test module 100 obtains the response signal in response to this test signal (S34).

The CPU 170 then compares the response signal with a predetermined value (S44). For example, the CPU 170 compares the voltage of the response signal with 3.5 V shown in FIG. 6. When the response signal has a voltage smaller than the predetermined value, the voltage of the test signal is reset to the lower limit (S45). For example, when the voltage of the response signal is smaller than 3.5 V for the test signal of a voltage 200 mV, the threshold signal has a voltage within a range from 200 mV to 250 mV. Therefore, the voltage 200 mV of the test signal is set to the lower limit voltage, and 250 mV is set to the upper limit voltage. When the response signal has a voltage larger than the predetermined value, the voltage of the test signal is reset to the upper limit (S46). For example, when the voltage of the response signal is larger than 3.5 V for the test signal of a voltage 200 mV, the threshold signal has a voltage within a range from 150 mV to 200 mV. Therefore, the voltage 200 mV of the test signal is set to the upper limit voltage, and 150 mV is set to the lower limit voltage. When the response signal has a voltage equal to the predetermined value, the test signal becomes the threshold signal.

When the response signal has a voltage smaller than or larger than the predetermined value, it is determined whether a difference between the upper limit voltage and the lower limit voltage is smaller than the input resolution (S54). When the difference between the upper limit voltage and the lower limit voltage of the test signal is larger than the input resolution, the processing at steps S24 to S54 are executed again. In this case, the upper limit voltage or the lower limit voltage of the test signal set at step S45 or S46 is used in the processing at step S24. For example, when 200 mV is set to the lower limit voltage and 250 mV is set to the upper limit voltage at step S45, 225 mV is set to the voltage of the test signal at step S24. This test signal is input to the DUT 400. Each time when the processing at steps S24 to S54 is executed repeatedly, the voltage range of the test signal is narrowed by one half, thereby searching the threshold signal as explained above.

When the difference between the upper limit voltage and the lower limit voltage of the test signal, i.e., the voltage range of the test signal, is smaller than the input resolution at step S54, the test signal becomes the threshold signal.

The processing at steps S24 to S54 is repeated until when the voltage of the response signal becomes equal to the predetermined value at step S44 or until when the difference between the upper limit voltage and the lower limit voltage of the test signal becomes smaller than the input resolution at step S54. The search method shown in FIG. 8 is hereinafter referred to as a dichotomizing search method. A test signal corresponding to a desired response signal is obtained according to this dichotomizing search method as well. This dichotomizing search method does not require the adder 113 shown in FIG. 3.

The dichotomizing search method makes it possible to specify a desired test signal in a shorter time than is required by the sequential search method. However, according to the dichotomizing search method, a test signal having a large difference in voltage is sequentially added to the DUT 400. Therefore, the measurement may be executed before the DUT 400 becomes in a steady state. Accordingly, the sequential search method is preferable to linearly test the DUT 400 in view of high precision.

The test module 100 can use other search method than those shown in FIG. 7 and FIG. 8.

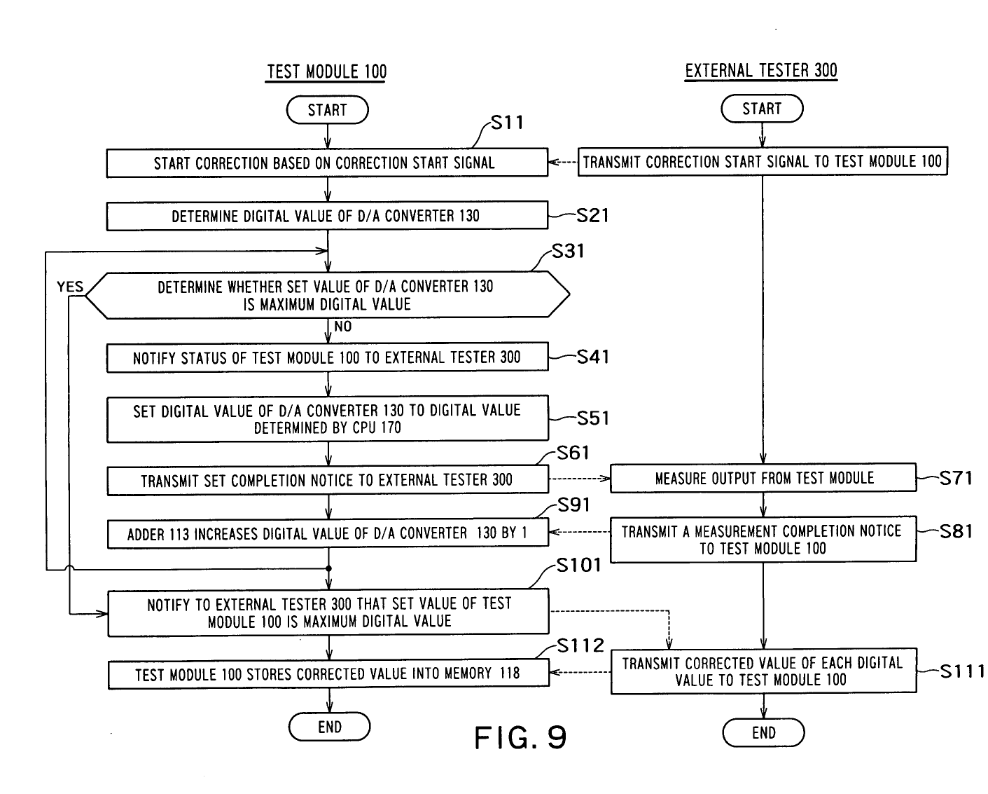

FIG. 9 is a flowchart of the correction operation of the test module 100. In some cases, the test signal that is actually output from the test module 100 includes an error in the test signal obtained based on the test condition information. Therefore, the test module 100 is corrected before the DUT 400 is tested. This correction is executed so that the test module 100 can accurately output the test signal based the test condition information. Accordingly, this correction is executed to the D/A converter 130 and the output buffer 140 shown in FIG. 3. The test signal output from the output buffer 140 is transmitted to the external tester 300.

The external tester 300 transmits a correction start signal to the test module 100. The test module 100 starts the correction based on this correction start signal (S11). The CPU 170 determines a digital value of the D/A converter 130 (S21). At the correction starting time, this digital value is determined as a minimum digital value among digital values that can be set in the D/A converter 130.

The CPU 170 then determines whether the set value of the D/A converter 130 is a maximum digital value among digital values that can be set in the D/A converter 130 (S31). When this set value is not the maximum digital value, the CPU 170 notifies to the external tester 300 that the set value of the test module 100 is not the maximum digital value (S41). The digital value of the D/A converter 130 is then set to the digital value determined by the CPU 170 (S51). The CPU 170 transmits to the external tester 300 a set completion notice that shows the completion of the setting of the D/A converter 130 (S61).

The external tester 300 then measures the output from the D/A converter 130 and the output from the output buffer 140 (S71). After finishing this measurement, the external tester 300 transmits a measurement completion notice to the test module 100 (S81).

The adder 113 then increases the digital value of the D/A converter 130 by 1 (S91), and the processing at steps S11 to S91 is repeated. The test module 100 changes the digital value of the D/A converter 130 in the ascending order, and the external tester 300 measures the voltage that is output from the test module 100 based on each digital value in the manner as described above.

When the digital value of the D/A converter 130 becomes the maximum value at step S31, the CPU 170 notifies to the external tester 300 that the set value of the test module 100 is the maximum digital value (S101). Upon receiving this notification, the external tester 300 transmits the corrected value of each digital value to the test module 100 (S111). The test module 100 stores the corrected value into the memory 118 (S112). The correction value is, for example, a difference voltage between an output from the test module 100 and an output from the external tester 300 under same test condition information.

The correction of the test module 100 is completed in this way. When the test module 100 tests the DUT 400, the correcting D/A converter 190 adds a correction value to the digital signal to be input to the D/A converter 130, thereby correcting the analog signal output from the D/A converter 130. When the test module 100 continuously executes a certain test item, this correction operation may be executed only once at the time of starting the test item.

In the present embodiment, the test module 100 tests the DUT 400 by changing the voltage of the test signal. Alternatively, with depending on the circuit configuration of the DUT 400, the test module 100 may test the DUT 400 by changing the current of the test signal.

### Second Embodiment

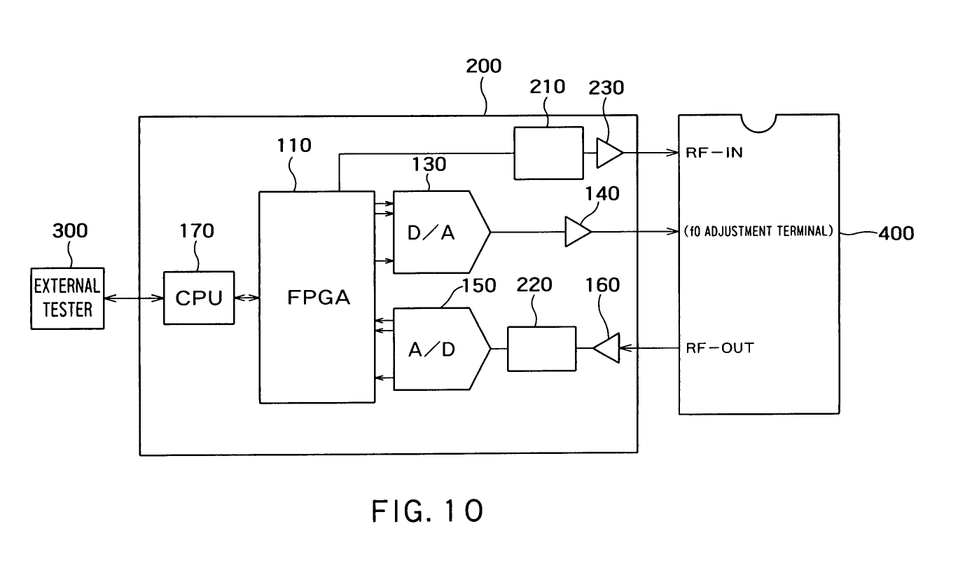

FIG. 10 is a block diagram of the configuration of a test module 200 according to a second embodiment of the present invention. In the present embodiment, the test module 200 includes an oscillator 210, and measures frequency characteristics of the AC filter within the DUT 400. Like constituent elements as those in the first embodiment are designated by like reference numerals.

The oscillator 210 oscillates upon receiving a signal from the FPGA 110. An output buffer 230 amplifies a signal from the oscillator 210, and supplies the amplified signal to a higher-frequency input RF-IN of the DUT 400 as a test signal. The oscillator 210 is a VCO (Voltage Controlled Oscillator) or a programmable SG (Signal Generator), for example. The frequency of the signal oscillated by the oscillator 210 can be changed based on the signal from the FPGA 110.

Further, in the present embodiment, a DC converter 220 is connected between the A/D converter 150 and the input buffer 160. A higher-frequency output RF-OUT of the DUT 400 outputs a response signal in response to the test signal. The input buffer 160 amplifies this response signal, and transmits the amplified signal to the DC converter 220. The DC converter 220 includes an integrating circuit to quantitatively convert the amplitude of an AC signal. The DC converter 220 is a RMC-DC (Root Mean Squared Value to Direct Current) converter.

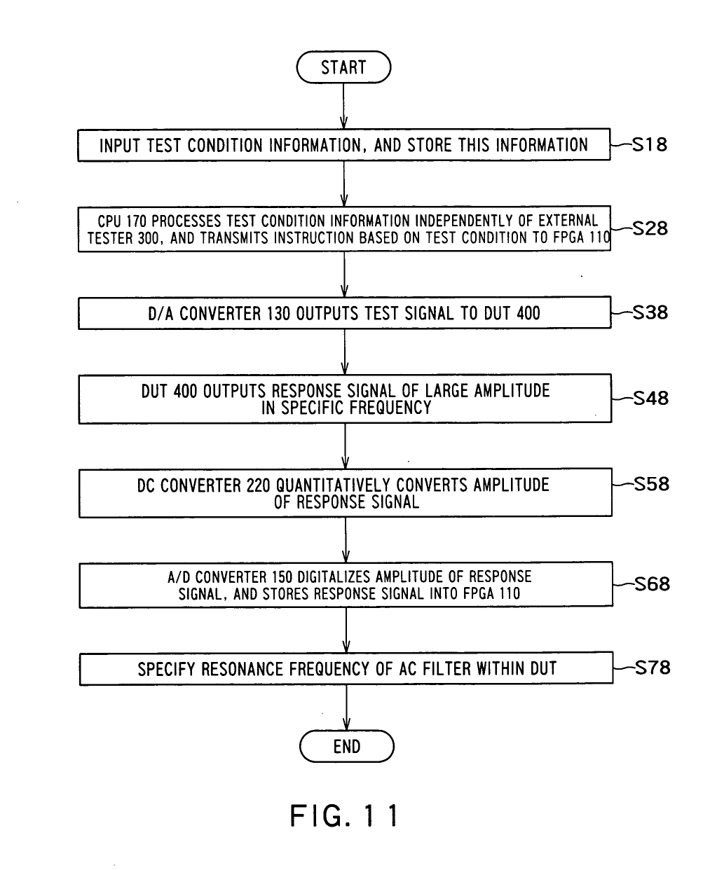

FIG. 11 is a flowchart of the test operation of the test module 200. The test module 200 inputs test condition information to test the DUT 400 from the external tester 300, and stores the test condition information into the FPGA 110 (S18). The test condition information includes a change range of a frequency of the test signal to be supplied to the DUT 400, a frequency step width for a staged change of the voltage of the test signal (hereinafter also referred to as input resolution), time period to supply the test signal to the DUT 400 at a certain frequency step, a method of searching a desired test signal within a change range of the test signal, and a response signal that becomes a basis of the search.

In the present embodiment, the CPU 170 also processes the test condition information independently of the external tester 300, and transmits an instruction based on the test condition to the FPGA 110 (S28). The FPGA 110 controls the D/A converter 130 following this instruction. The D/A converter 130 outputs the test signal of the frequency based on the test condition information to the DUT 400 (S38). The oscillator 210 changes the frequency of the test signal within the change range of the test signal. In this case, the oscillator 210 changes the frequency of the test signal at stages for each input resolution.

The AC filter within the DUT 400 oscillates with a test signal of a specific frequency. Therefore, the DUT 400 outputs a response signal of large amplitude in this specific frequency (S48). The DC converter 220 quantitatively converts the amplitude of the response signal (S58). Thereafter, the A/D converter 150 digitalizes the amplitude of the response signal, and stores the response signal into the FPGA 110 (S68). In this case, the frequency of the test signal and the amplitude of the corresponding response signal are stored into the FPGA 110 in relation to each other.

The FPGA 110 specifies the frequency of the test signal when the response signal has a maximum amplitude, as a resonance frequency of the AC filter (S78). In this way, the test module 200 can search the frequency characteristics of the AC filter within the DUT 400.

The test module 200 can search the frequency characteristics of the AC filter by using the dichotomizing search method. The dichotomizing search method makes it possible to specify a desired test signal in a shorter time than is required by the sequential search method. However, as described above, the sequential search method is preferable to linearly test the DUT 400 in view of high precision.

The test module 200 executes the test independently of the test carried out by the external tester 300. In order to avoid a mutual interference between the signal concerning the test carried out by the external tester 300 and the signal concerning the test carried out by the test module 200, the test module 200 tests a circuit portion electrically isolated from a circuit portion that the external tester 300 tests during the same period. As a result, the test module 200 can test the same DUT 400 in parallel with the external tester 300.

Accordingly, the provision of the module 200 in parallel with the external tester 300 can shorten the time to test the DUT 400. One or more modules can be provided. The provision of two or more test modules 200 in parallel with the external tester 300 can further shorten the time required to test the DUT 400.

1. A semiconductor test module comprising:
an interface that inputs test condition information showing a test condition of a subject to be tested from an external testing device which tests electric characteristics of the subject, and that outputs test result information showing a result of testing the subject to the external testing device;
a first storage section that stores the test condition information;
a processor that processes the test condition information independently of the external testing device;
an output section that outputs a test signal based on the test condition information to the subject in parallel with the external testing device, following an instruction from the processor;
an input section that inputs a response signal from the subject in response to the test signal; and
a second storage section that stores information based on the response signal as the test result information.

2. The semiconductor test module according to claim 1, wherein
the interface inputs a test starting signal to start the test from the external testing device, and
the processor starts to process the test condition information based on the test starting signal.

3. The semiconductor test module according to claim 1, wherein
the test condition information and the test result information are digital signals,
the output section includes a D/A converter that converts the test condition information into an analog signal and that outputs the analog signal to the subject as the test signal, and
the input section includes an A/D converter that inputs the response signal as an analog signal, and converts the response signal into the test result signal which is a digital signal.

4. The semiconductor test module according to claim 1, wherein
the test condition information includes information of a voltage change range of the test signal, and information concerning a step width to change at stages the voltage of the test signal, and
the output section sequentially changes the voltage of the test signal at stages following the step width within the change range, and outputs a changed voltage to the subject.

5. The semiconductor test module according to claim 1, wherein
the test condition information includes information of a current change range of the test signal, and information concerning a step width to change at stages the current of the test signal, and
the output section sequentially changes the current of the test signal at stages following the step width within the change range, and outputs a changed current to the subject.

6. The semiconductor test module according to claim 1, wherein
the test condition information includes information of a frequency change range of the test signal, and information concerning a step width to change at stages the frequency of the test signal, and
the output section sequentially changes the frequency of the test signal at stages following the step width within the change range, and outputs a changed frequency to the subject.

7. The semiconductor test module according to claim 1, wherein the semiconductor test module tests the subject by using a sequential search method.

8. The semiconductor test module according to claim 1, wherein the semiconductor test module tests the subject by using a dichotomizing search method.

9. The semiconductor test module according to claim 1, further comprising:
a correction signal generating section that corrects a test signal output from the output section in a case that a test signal output from the output section includes an error in a test signal based on the test condition information.

10. A method of testing a semiconductor device for testing a subject by using a semiconductor test module, the test module having an interface communicable with an external testing device which tests electric characteristics of the subject, a processor that processes information from the interface, an output section that outputs a test signal for testing the subject to the subject, and an input section that inputs a response signal from the subject in response to the test signal, wherein
the method of testing a semiconductor device comprises:
inputting test condition information via the interface, the test condition information showing a condition for testing the subject from the external testing device;
processing the test condition information in the processor independently of the external testing device;
outputting the test signal based on the test condition information from the output section to the subject in parallel with the external testing device; and
inputting the response signal via the input section.

11. The method of testing a semiconductor device according to claim 10, wherein
during inputting the test condition information, the interface, further, inputs a test starting signal to start the test from the external testing device, and
when the test condition information is processed, the processor starts to process the test condition information based on the test starting signal.

12. The method of testing a semiconductor device according to claim 10, wherein
the test condition information includes information of a voltage change range of the test signal, and information concerning a step width to change at stages the voltage of the test signal, and
during outputting the test signal, the output section sequentially changes the voltage of the test signal at stages following the step width within the change range, and outputs a changed voltage to the subject.

13. The method of testing a semiconductor device according to claim 10, wherein
the test condition information includes information of a current change range of the test signal, and information concerning a step width to change at stages the current of the test signal, and
during outputting the test signal, the output section sequentially changes the current of the test signal at stages following the step width within the change range, and outputs a changed current to the subject.

14. The method of testing a semiconductor device according to claim 10, wherein
the test condition information includes information of a frequency change range of the test signal, and information concerning a step width to change at stages the frequency of the test signal, and
during outputting the test signal, the output section sequentially changes the frequency of the test signal at stages following the step width within the change range, and outputs a changed frequency to the subject.

15. The method of testing a semiconductor device according to claim 10, wherein
the semiconductor test module further includes a correction signal generating section that corrects a test signal output from the output section, and
the method of testing a semiconductor device further comprises:
determining whether the test signal output from the output section includes an error in the test signal based on the test condition information in the external testing device, prior to outputting the test signal, wherein:
during outputting the test signal, the correction signal generating section adds a correction signal to the test signal to correct the test signal from the external testing device, in case that the test signal output from the output section has an error in the test signal based on the test condition information.

16. The method of testing a semiconductor device according to claim 10, wherein the method of testing a semiconductor device executes the tests of the subject by using a sequential search method.

17. The method of testing a semiconductor device according to claim 10, wherein the method of testing a semiconductor device executes the tests of the subject by using a dichotomizing search method.
